(19) United States
(12) Patent Application Publication
(10) Pub. No.: US 2016/0291216 A1
(43) Pub. Date: Oct. 6, 2016

(54) OPTICAL FILM AND DISPLAY DEVICE COMPRISING THE SAME

(71) Applicant: SAMSUNG DISPLAY CO., LTD., Yongin-si (KR)

(72) Inventor: Dukjin Lee, Suwon-si (KR)

(21) Appl. No.: 15/003,623

(22) Filed: Jan. 21, 2016

(30) Foreign Application Priority Data
Mar. 31, 2015 (KR) 10-2015-0045069

(51) Int. Cl. G02B 5/02; H01L 51/52; G02B 1/04

(52) U.S. Cl. CPC G02B 5/0263; G02B 5/0242; G02B 5/0278; G02B 1/04; H01L 51/5268

(57) ABSTRACT

An optical film includes: a low haze portion having a haze value of about 60% or less; and a high haze portion having a haze value of about 80% or more. The high haze portion may be disposed in an outer side of the low haze portion.

### CROSS-REFERENCE TO RELATED APPLICATION

Any and all applications for which a foreign or domestic priority claim is identified in the Application Data Sheet as filed with the present application are hereby incorporated by reference under 37 CFR 1.57. This application claims priority to and the benefit of Korean Patent Application No. 10-2015-0045069, filed on Mar. 31, 2015, with the Korean Intellectual Property Office, the disclosure of which is incorporated herein in its entirety by reference.

### BACKGROUND

1. Field

The present disclosure relates to an optical film having a gradient in a haze value and a display device including the optical film.

2. Description of the Related Technology

In recent times, display devices have drawn attention, which display images using a liquid crystal display (LCD) panel, a plasma display panel (PDP), an electro luminescence display (ELD) panel, and an organic light emitting display (OLED) panel. Such display devices may be manufactured into a flat type or a curved type. In addition, wearable display devices have also been developed recently. Since the display devices have an edge portion that is bent, the wearable display devices may have a relatively great viewing angle in the edge portion and white angular dependency (“WAD”) phenomenon may be notably observed in the edge portion thereof.

As the viewing angle increases, a light diffusion film may be used to improve WAD phenomenon occurring in the display device. However, the light diffusion film may have limitations in improving WAD occurring in an edge portion of the display device that is curved.

It is to be understood that this background of the technology section is intended to provide useful background for understanding the technology and as such disclosed herein, the technology background section may include ideas, concepts or recognitions that were not part of what is known or appreciated by those skilled in the pertinent art prior to a corresponding effective filing date of subject matter disclosed herein.

### SUMMARY

The present disclosure of invention is directed to an optical film designed to improve white angular dependency (WAD) of a display device.

Further, the present disclosure is directed to a display device including the optical film.

According to an embodiment, an optical film includes: a low haze portion having a haze value of about 60% or less; and a high haze portion having a haze value of about 80% or more. The high haze portion may be disposed in an outer side of the low haze portion.

The low haze portion may have a haze value in a range of about 30% to about 60%.

The low haze portion may have a haze gradient in which a haze value increases along a direction from a center portion to an edge portion.

The high haze portion may have a haze value in a range of about 80% to about 98%.

The high haze portion may have a haze gradient in which a haze value increases along a direction from a center portion to an edge portion.

The optical film may further include at least one intermediate portion between the low haze portion and the high haze portion.

The intermediate portion may have a haze value in a range of about 60% to about 80%.

The low haze portion and the high haze portion may include a light transmission member and light scattering particles dispersed within the light transmission member.

The light scattering particle may include at least one of an acrylic resin, a polystyrene (PS) resin, a polyvinyl chloride resin, a polycarbonate (PC) resin, a polyethylene terephthalate (PET) resin, a polyethylene (PE) resin, a polypropylene (PP) resin, a polyimide (PI) resin, glass and silica.

The light transmission member may include at least one of a polyester resin, an acrylic resin, a cellulose resin, a polyolefin resin, a polyvinyl chloride resin, a polycarbonate resin, a phenolic resin and a urethane resin.

According to another embodiment, a display device includes: a display panel; and an optical film on the display panel. The optical film may include a low haze portion having a haze value of about 60% or less and a high haze portion having a haze value of about 80% or more. The high haze portion may be disposed in an outer side of the low haze portion.

The low haze portion may have a haze value in a range of about 30% to about 60%.

The low haze portion may have a haze gradient in which a haze value increases along a direction from a center portion to an edge portion.

The high haze portion may have a haze value in a range of about 80% to about 98%.

The high haze portion may have a haze gradient in which a haze value increases along a direction from a center portion to an edge portion.

The display device may further include at least one intermediate portion between the low haze portion and the high haze portion.

The intermediate portion may have a haze value in a range of about 60% to about 80%.

The low haze portion and the high haze portion may include a light transmission member and light scattering particles dispersed within the light transmission member.

The light scattering particle may include at least one of an acrylic resin, a polystyrene (PS) resin, a polyvinyl chloride resin, a polycarbonate (PC) resin, a polyethylene terephthalate (PET) resin, a polyethylene (PE) resin, a polypropylene (PP) resin, a polyimide (PI) resin, glass and silica.

The light transmission member may include at least one of a polyester resin, an acrylic resin, a cellulose resin, a polyolefin resin, a polyvinyl chloride resin, a polycarbonate resin, a phenolic resin and a urethane resin.

The display panel may include: a substrate; a first electrode on the substrate; an organic light emitting layer on the first electrode; and a second electrode on the organic light emitting layer.

The display panel may further include a thin film encapsulation layer on the second electrode.

According to the embodiments, an optical film may have an edge portion which has a haze value greater than a haze value of a center portion thereof, and thus may be efficient in preventing WAD occurring in an edge portion of a display device including the optical film. Further, according to other embodiments, the optical film may have a haze value gradually increasing from the center portion thereof toward the edge portion thereof, and thus a boundary interface may not be noticed.

The foregoing is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

The above and other features and aspects of the present disclosure will be more clearly understood from the following detailed description taken in conjunction with the accompanying drawings, in which:

FIG. 1 is a perspective view illustrating an optical film according to a first exemplary embodiment of the present invention;

FIG. 2 is a cross-sectional view taken along line I-I′ of FIG. 1;

FIG. 3 is a haze value graph based on position of the optical film according to the first exemplary embodiment;

FIG. 4 is a cross-sectional view illustrating an optical film according to a second exemplary embodiment;

FIG. 5 is a plan view illustrating an optical film according to a third exemplary embodiment;

FIGS. 6 and 7 are mimetic diagrams illustrating a path of light passing through light scattering particles, respectively;

FIG. 8 is a mimetic diagram illustrating a path of light passing through an optical film;

FIGS. 9A through 9C are cross-sectional views illustrating processes of manufacturing the optical film according to the first exemplary embodiment;

FIG. 10 is a view illustrating a structure of a display device according to a fourth exemplary embodiment;

FIG. 11 is a plan view illustrating portion “A” of FIG. 10;

FIG. 12 is a cross-sectional view taken along line II -II′ of FIG. 11;

FIG. 13 is a cross-sectional view illustrating a display device according to a fifth exemplary embodiment;

FIG. 14 is a schematic view illustrating a viewing angle of a user looking at a display device;

FIG. 15 is a graph illustrating a WAD improvement rate and a transmittance based on a haze value of an optical film; and

FIG. 16 is a graph illustrating WAD improvement.

### DETAILED DESCRIPTION OF CERTAIN INVENTIVE EMBODIMENTS

Hereinafter, specific embodiments of the present disclosure will be described in more detail with reference to the accompanying drawings. The present embodiments may, however, be represented in many different forms and should not be construed as being limited to the specific embodiments set forth herein. Rather, these specific embodiments are provided so that this disclosure will be thorough and complete, and will fully convey the scope of the embodiments to those skilled in the art.

In the drawings, certain elements or shapes may be simplified or exaggerated to better illustrate the present embodiments, and other elements present in an actual product may also be omitted. Thus, the drawings are intended to facilitate the understanding of the present embodiments. Like reference numerals refer to like elements throughout the specification.

In addition, when a layer or element is referred to as being “on” another layer or element, the layer or element may be directly on the other layer or element, or one or more intervening layers or elements may be interposed therebetween.

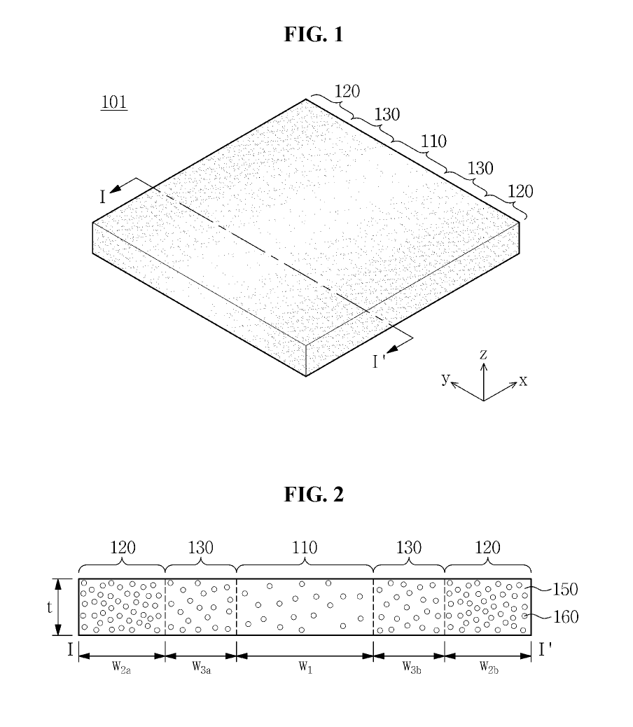

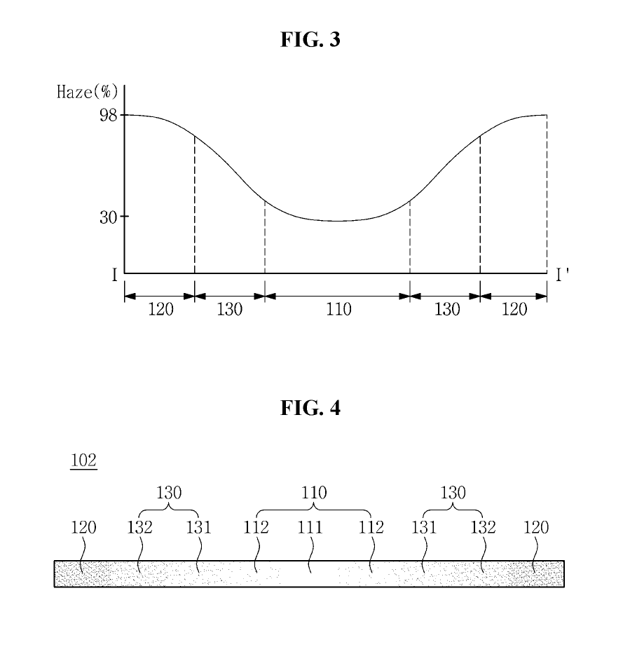

Hereinafter, a first exemplary embodiment of the present disclosure will be described with reference to FIGS. 1 and 2.

FIG. 1 is a perspective view illustrating an optical film 101 according to the first exemplary embodiment of the present disclosure. FIG. 2 is a cross-sectional view taken along line I-I′ of FIG. 1.

The optical film 101 according to the first exemplary embodiment may have a low haze portion 110 having a haze value of about 60 percent (%) or less, and a high haze portion 120 having a haze value of about 80% or more. The high haze portion 120 may be disposed in an outer side of the low haze portion 110.

The optical film 101 according to the first exemplary embodiment may include a light transmission member 150 and light scattering particles 160 dispersed within the light transmission member 150. In other words, the low haze portion 110 and the high haze portion 120 may include the light transmission member 150 and the light scattering particles 160 dispersed within the light transmission member 150.

Based on an amount of the light scattering particles 160 dispersed within the light transmission member 150, a haze value may be adjusted. The high haze portion 120 may include the light scattering particles 160 more than the low haze portion 110 does.

The light transmission member 150 may be made of a light transmission resin that may transmit light. Any material that may impart light transmission properties may be used as the light transmission member 150. The light transmission member 150 may include a material that is light-weight, cost-effective, and easy to handle. By way of example, the light transmission member 150 may include at least one of a polyester resin, an acrylic resin, a cellulose resin, a polyolefin resin, a polyvinyl chloride resin, a polycarbonate resin, a phenolic resin and a urethane resin. Among the aforementioned materials for forming the light transmission member 150, in more particular, the polyester resin, the polycarbonate resin, or the acrylic resin, which have a suitable balance between rigidity and flexibility, may be used as the light transmission member 150.

The polyester resin may be formed of an aromatic monomer, such as terephthalic acid, isophthalic acid, and naphthalene dicarboxylic acid, and a glycol.

The polycarbonate resin may be made through reaction of bisphenol and diaryl carbonate and a melt transesterification method.

The acrylic resin may include, for example, an acrylic copolymer. Examples of the acrylic copolymer may include a copolymer in which a (meth)acrylate monomer containing an alkyl group having 1 to 14 carbon atoms is polymerized along with a monomer containing a cross-linking functional group. Herein, “(meth)acrylate” refers to acrylate or methacrylate.

Examples of the (meth)acrylate monomer having 1 to 14 carbon atoms may include methyl (meth)acrylates, ethyl (meth)acrylates, n-butyl (meth)acrylates, s-butyl (meth)acrylates, t-butyl (meth)acrylates, isobutyl (meth)acrylates, hexyl (meth)acrylates, 2-ethylhexyl (meth)acrylates, n-octyl (meth)acrylates, isooctyl (meth)acrylates, n-nonyl (meth)acrylates, isononyl (meth)acrylates, n-decyl (meth)acrylates, isodecyl (meth)acrylates, n-dodecyl (meth)acrylates, n-tridecyl (meth)acrylates, n-tetradecyl (meth)acrylates, pentafluoro octyl acrylates, and 6-(1-naphthyloxy)-1-hexyl acrylates. Such examples of the (meth)acrylate monomer may be used alone or in combination of two or more kinds thereof

Examples of the monomer including the functional group may include a monomer containing a sulfonic acid group, a monomer containing a phosphoric acid group, a monomer containing a cyano group, a vinyl ester, an aromatic vinyl compound, a monomer containing a carboxyl group, a monomer containing an acid anhydride group, a monomer containing a hydroxyl group, a monomer containing an amide group, a monomer containing an amino group, a monomer containing an imide group, a monomer containing an epoxy group and a monomer containing an ether group. Such examples of the monomer including the functional group may be used alone or in combination of two or more kinds thereof.

The light scattering particles 160 may serve to scatter and diffuse light. Any material that may impart light diffusion properties may be used as the light scattering particle 160 without limitation. The size of the light scattering particles 160 and the amount thereof within the light transmission member 150 may affect the haze value and the light diffusion efficiency of the optical film 101.

As the particle size of the light scattering particles 160 decreases, an effect of increasing a haze value is enhanced, provided that the same amount by weight is used. However, as the particle size of the light scattering particles 160 decreases, dispersion property of the light scattering particles 160 is deteriorated.

For example, when an average particle diameter of the light scattering particles 160 is less than about 1 micrometer (μm), the compatibility with the light transmission member 150 may be diminished. Additionally, when an average particle diameter of the light scattering particles 160 is more than about 20 μm, the optical film 101 may not exhibit excellent efficiency in increasing light scattering and may have a difficulty in achieving a small thickness. Therefore, the light scattering particles 160 may have an average particle diameter in a range of about 1 μm to about 2 μm. However, the average particle diameter of the light scattering particles 160 may not be limited to the aforementioned range, and may thus vary based on a purpose of use thereof.

The shape of the light scattering particles 160 may not be particularly limited. The light scattering particles 160 may have, for example, a spherical or elliptical shape.

The light scattering particles 160 may be used in an amount of about 5 percentage by weight (wt %) to about 50 wt % with respect to 100 wt % of the light transmission member 150 or may be used in an amount of about 20 wt % to about 40 wt % with respect thereto. In a case where the amount of the light scattering particles 160 is less than about 5 wt % with respect to 100 wt % of the light transmission member 150, the light scattering efficiency may be diminished. On the other hand, in a case where the amount of the light scattering particles 160 is more than about 50 wt % with respect thereto, the light transmission property or durability of the optical film 101 may be diminished.

The light scattering particles 160 may include, for example, at least one of an acrylic resin, a polystyrene (PS) resin, a polyvinyl chloride resin, a polycarbonate (PC) resin, a polyethylene terephthalate (PET) resin, a polyethylene (PE) resin, a polypropylene (PP) resin, a polyimide (PI) resin, glass and silica. For example, the light scattering particle 160 may be a polystyrene particle. Examples of the polystyrene particle may include a styrene polymer or an acrylic-styrene copolymer.

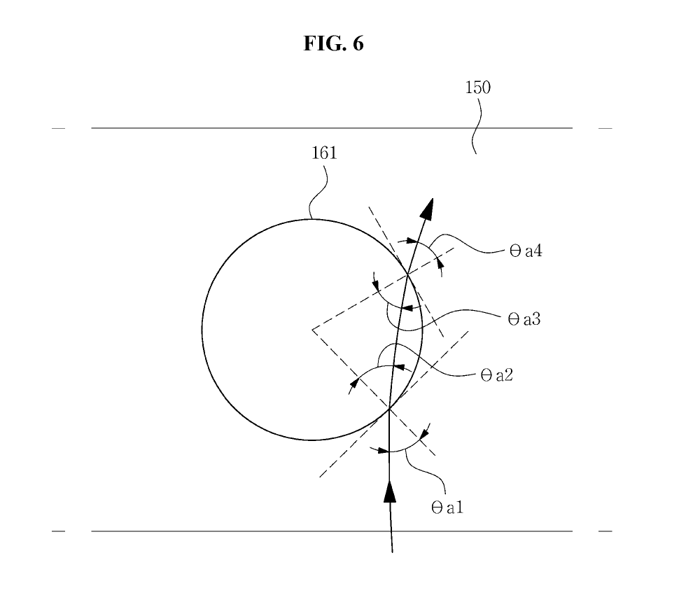

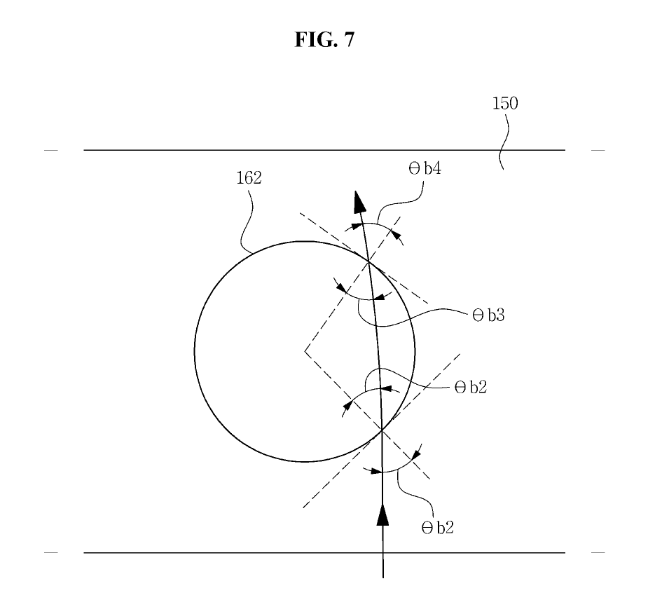

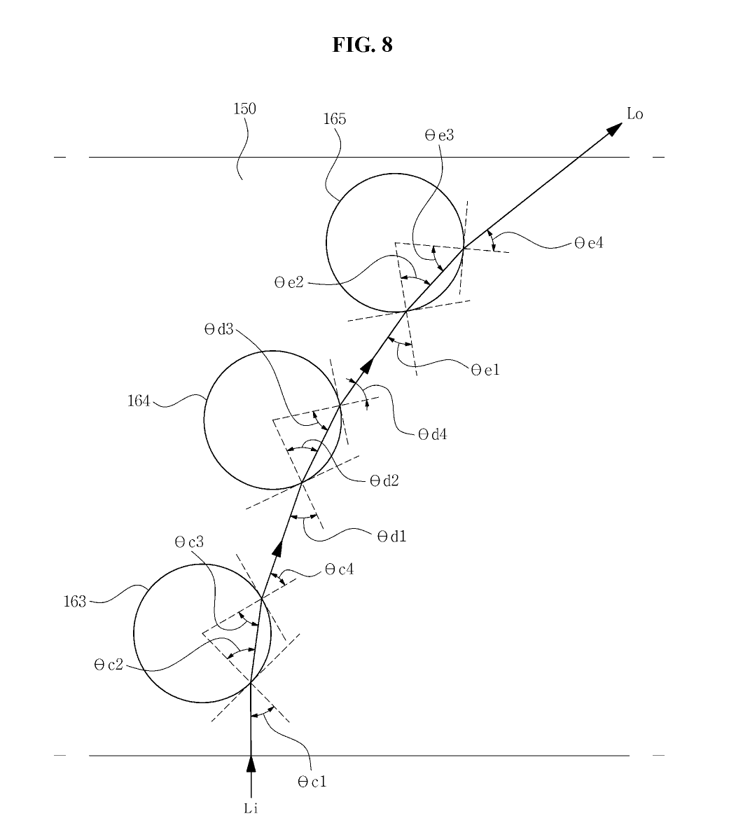

A refractive index of the light scattering particles 160 may be more than or less than the refractive index of the light transmission member 150. Based on a difference between the refractive indices of the light scattering particles 160 and the light transmission member 150, a path of light passing through the light scattering particles 160 and a degree of light diffusion may vary (refer to FIGS. 6 and 7). As such, when light is diffused by the light scattering particles 160, light paths thereof may be changed and lights having different light paths may be mixed together, such that color shift may be prevented.

By adjusting the refractive index of the light scattering particles 160, the light diffusion property and a haze value of the optical film 101 may be adjusted.

A difference between the refractive indices of the light transmission member 150 and the light scattering particles 160 may be in a range of about 0.1 to about 2.0. In a case where the difference between the refractive indices of the light transmission member 150 and the light scattering particles 160 is less than about 0.1, an effect of the light scattering may be subtle; on the other hand, in a case where the difference therebetween is more than about 2.0, light refraction may be excessive, and thus the optical film 101 may be disadvantageous in light extraction.

For example, the light transmission member 150 may have a refractive index in a range of about 1.4 to about 1.6, and the light scattering particles 160 may have a refractive index of about 1.3 to about 3.0.

The optical film 101 according to the first exemplary embodiment may include the low haze portion 110 disposed in a center portion of the optical film 101 and the high haze portion 120 disposed in an edge portion thereof. In other words, the edge portion of the optical film 101 may have a greater haze value than that of the center portion thereof.

Further, referring to FIGS. 1 and 2, the optical film 101 may include an intermediate portion 130 disposed between the low haze portion 110 and the high haze portion 120. The intermediate portion 130 may have a haze value greater than that of the low haze portion 110 and less than that of the high haze portion 120. However, the first exemplary embodiment of the present invention is not limited thereto, and the optical film 101 may have more subdivided portions based on the distribution of the haze value, and may have two or more intermediate portions.

In the optical film 101 illustrated in FIG. 1, the low haze portion 110, the high haze portion 120, and the intermediate portion 130 may be arranged along an x-axis, while being parallel to each other. In this regard, the intermediate portions 130 may be disposed on both sides of the low haze portion 110, and the high haze portions 120 may be disposed on both sides of the intermediate portion 130. Herein, the x-axis denotes a length direction, a y-axis denotes a width direction, and a z-axis denotes a thickness direction.

The low haze portion 110, the high haze portion 120, and the intermediate portion 130 may have widths that may vary in accordance with the purpose of use of the optical film 101 and needs of users.

A width w1 of the low haze portion 110 may account for about 30% to about 70% of a total width of the optical film 101. In other words, the low haze portion 110 may account for about 30% to about 70% of a total area of the optical film 101. For example, the width w1 of the low haze portion 110 may account for about 45% to about 55% of a total width of the optical film 101.

A total width (w3a+w3b) of the intermediate portions 130 disposed on the both sides of the low haze portion 110 may account for about 15% to about 35% of the total width of the optical film 101, for example, about 25%. A total width (w2a+w2b) of the high haze portions 120 disposed on the both sides of the intermediate portions 130 may account for about 15% to about 35% of the entire width of the optical film 101, for example, 25%.

In addition, the optical film 101 may have a thickness in a range of about 20 μm to about 100 μm. In a case where the thickness of the optical film 101 is more than about 20 μm, a stable physical and mechanical property and thermal-resistance may be secured; and in a case where the thickness thereof is less than about 100 μm, flexibility and a slim structure may be achieved.

In general, a haze value of an optical film may be calculated as a ratio of a diffused light to an entire light that passes through the optical film. In other words, the haze value of the optical film may be calculated by the following Formula 1.

Haze (%)=[(diffused light)/(entire transmission light)]×100 [FORMULA 1]

As an amount of the light scattering particles 160 increases to increase the haze value of the optical film 101, light diffusion may be efficiently performed. On the contrary, when the haze value of the optical film 101 is excessively great, light transmittance of the optical film 101 may be diminished.

In detail, the low haze portion 110 may have a haze value in a range of about 30% to about 60%, and the high haze portion 120 may have a haze value in a range of about 80% to about 98%. In addition, the intermediate portion 130 may have a haze value in a range of about 60% to about 80%.

In order to prevent visibility of a boundary interface formed due to a difference in a haze value based on position, the optical film 101 may have a haze value gradually increasing along a direction from the center portion of the optical film 101 toward the edge portion thereof. In other words, the haze value of the optical film 101 may exhibit a gradient.

In detail, the low haze portion 110 may have a haze gradient in which the haze value increases along a direction from the center portion of the optical film 101 toward the edge portion thereof. The high haze portion 120 may also have a haze gradient in which the haze value increases along a direction from the center portion of the optical film 101 toward the edge portion thereof. In addition, the intermediate portion 130 may have a haze gradient in which the haze value increases along a direction from the low haze portion 110 toward the high haze portion 120.

FIG. 3 is a haze value graph of the optical film 101 according to the first exemplary embodiment. With respect to a y-axis, which is a width direction, the haze value may gradually increase along a direction from the center portion of the optical film 101 toward the edge portion thereof.

The optical film 101 according to the first exemplary embodiment may be used in a display device. Since a lateral surface of a display device may have a viewing angle greater than that of a front surface, the lateral surface may exhibit relatively significant color shift.

Therefore, the high haze portion 120 of the optical film 101 may be disposed in the lateral surface of the display device so as to suppress color shift of light occurring in the lateral surface of the display device, and the low haze portion 110 of the optical film 101 may be disposed in the front surface of the display device so as to prevent a decrease in light transmittance of the display device.

Hereinafter, a second exemplary embodiment will be described with reference to FIG. 4.

FIG. 4 is a cross-sectional view illustrating an optical film 102 according to the second exemplary embodiment. The optical film 102 according to the second exemplary embodiment may include a low haze portion 110, a high haze portion 120, and an intermediate portion 130. Further, the optical film 102 according to the second exemplary embodiment may have a haze gradient in which a haze value increases along a direction from a center portion of the optical film 102 toward an edge portion thereof.

The low haze portion 110 may have a first low haze portion 111 and second low haze portions 112 disposed on both sides of the first low haze portion 111. The second low haze portion 112 may have a greater haze value than that of the first low haze portion 111.

The intermediate portions 130 may be disposed on both sides of the low haze portion 110. The intermediate portion 130 may include a first intermediate portion 131 disposed adjacent to the second low haze portion 112 and a second intermediate portion 132 disposed adjacent to the first intermediate portion 131. The first intermediate portion 131 may have a greater haze value that that of the second low haze portion 112, and the second intermediate portion 132 may have a greater haze value than that of the first intermediate portion 131.

The high haze portion 120 may be disposed adjacent to the intermediate portion 130 to be disposed in the edge portion of the optical film 102. The high haze portion 120 may have a greater haze value than that of the second intermediate portion 132.

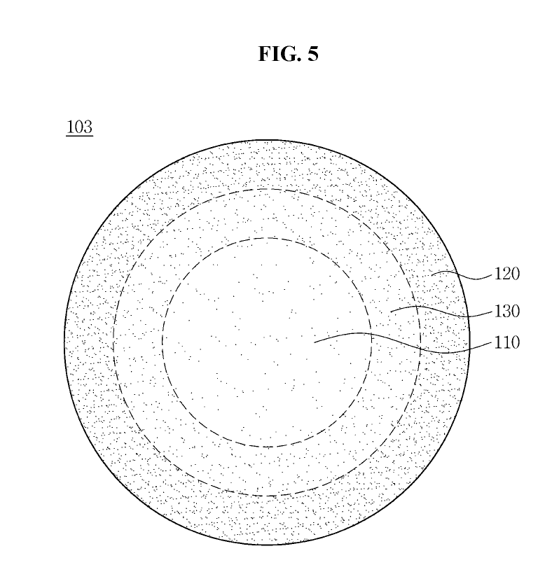

Hereinafter, a third exemplary embodiment will be described with reference to FIG. 5.

FIG. 5 is a plan view illustrating an optical film 103 according to the third exemplary embodiment. The optical film 103 according to the third exemplary embodiment may have a circular shape, and may include a low haze portion 110 disposed in a center portion of the optical film 103, an intermediate portion 130 surrounding the low haze portion 110, and a high haze portion 120 surrounding the intermediate portion 130.

The optical film 103 according to the third exemplary embodiment may have a haze gradient in which a haze value increases along a direction from the center portion of the optical film 103 toward the edge portion thereof. The intermediate portion 130 may have a greater haze value than that of the low haze portion 110, and the high haze portion 120 may have a greater haze value than that of the intermediate portion 130.

The optical film 103 according to the third exemplary embodiment may be used in manufacturing of a circular-shaped display device. In other words, the optical film 103 according to the third exemplary embodiment may be disposed in a circular-shaped display panel. Examples of the circular-shaped display device may include wearable display devices. The wearable display device may include, for example, a smart watch.

FIGS. 6 and 7 are mimetic diagrams illustrating a path of light passing through light scattering particles 161 and 162 dispersed in the light transmission member 150, respectively.

FIG. 6 illustrates a case in which the refractive index of the light scattering particle 161 is less than a refractive index of the light transmission member 150. A light which is incident, at an angle θa1, onto the light scattering particle 161 at a spatial point of the light scattering particle 161 may be refracted at an angle θa2, and then may be incident, at an angle θa3, at another spatial point of the light scattering particle 161 toward the light transmission member 150 to be refracted at an angle θa4. Referring to FIG. 6, the light incident to the light scattering particle 161 may be refracted to the right with respect to an incident direction.

FIG. 7 illustrates a case in which a refractive index of the light scattering particle 162 is greater than the refractive index of the light transmission member 150. A light which is incident, at an angle θb1, onto the light scattering particle 162 at a spatial point of the light scattering particle 162 may be refracted at an angle θb2, and then may be incident, at an angle θb3, at another spatial point of the light scattering particle 162 toward the light transmission member 150 to be refracted at an angle θb4. Referring to FIG. 7, the light incident to the light scattering particle 162 may be refracted to the left with respect to an incident direction.

Hereinafter, a light path of light incident onto the optical film 101 according to the first exemplary embodiment will be described in more detail with reference to FIG. 8.

FIG. 8 is a mimetic diagram illustrating a path of light passing through the optical film 101. Referring to FIG. 8, an incident light Li may pass through a first light scattering particle 163, a second light scattering particle 164, and a third light scattering particle 165 to be directed outwards as a light Lo.

Subsequent to being incident onto the optical film 101, the incident light Li may be incident, at an angle θc1, at a spatial point of the first light scattering particle 163 into the first light scattering particle 163 to be refracted at an angle θc2, and then may be incident, at an angle θc3, at another spatial point of the first light scattering particle 163 toward the light transmission member 150 to be refracted at an angle θc4. Subsequently, the incident light Li may repeat incidence and refraction at angles θd1, θd2, θd3, and θd4 while passing through the second light scattering particle 164, and then may repeat incidence and refraction at angles θe1, θe2, θe3, and θe4 while passing through the third light scattering particle 165. As a result, the incident light Li may be refracted in a direction that is different from an incident direction to be directed outwards from the optical film 101 as the light Lo.

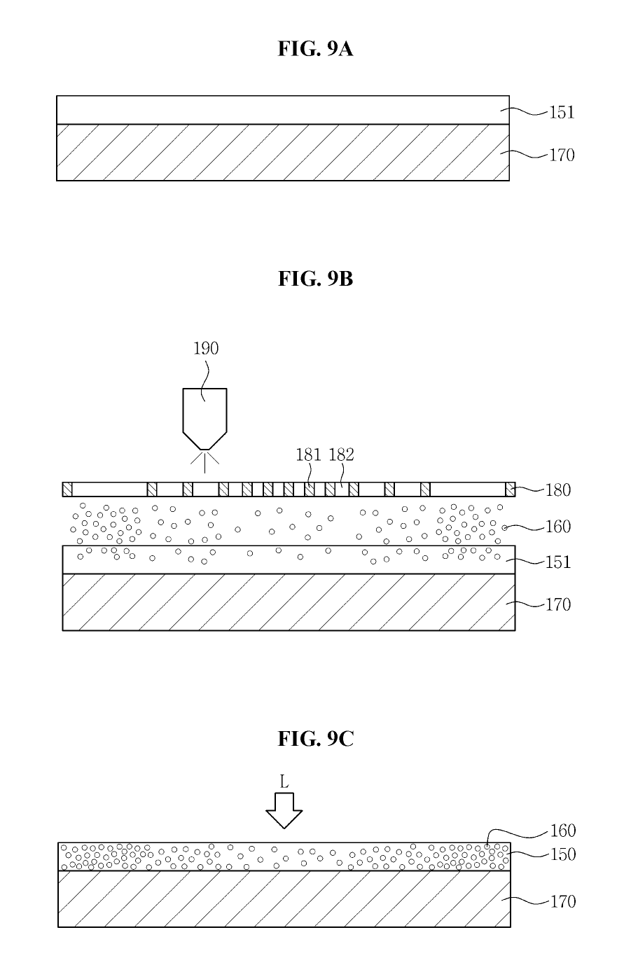

Hereinafter, processes of manufacturing the optical film 101 according to the first exemplary embodiment will be described with reference to FIGS. 9A through 9C.

First, a light transmission member-forming composition 151 may be coated, in a film form, on a sheet 170 having a release property (refer to FIG. 9A).

Subsequent to a screen 180 being disposed on the light transmission member-forming composition 151, which is coated in a film form, screen printing may be carried out (refer to FIG. 9B). The screen 180 may have a shielding portion 181 and a transmission portion 182. An interval between the shielding portions 181 may be narrow in a center portion of the screen 180 and may widen toward an edge portion thereof. Accordingly, a ratio of the transmission portion 182 provided in a unit area of the center portion of the screen 180 may be less than a ratio of the transmission portion 182 provided in the unit area of the edge portion thereof.

Light scattering particles 160 may be sprayed on the screen 180 using a spray nozzle 190 to perform the screen printing. Through the performing of the screen printing, the light scattering particles 160 may infiltrate into the light transmission member-forming composition 151. Accordingly, the light scattering particles 160 in a relatively small amount, compared to an amount of the light scattering particles in an edge portion of the light transmission member-forming composition 151, may infiltrate into a center portion of the light transmission member-forming composition 151.

Subsequently, light may be irradiated onto the light transmission member-forming composition 151 into which light scattering particles 160 infiltrate, and the light transmission member-forming composition 151 may be cured, thus forming the optical film 101 (refer to FIG. 9C). The light transmission member-forming composition 151 may be cured to form the light transmission member 150.

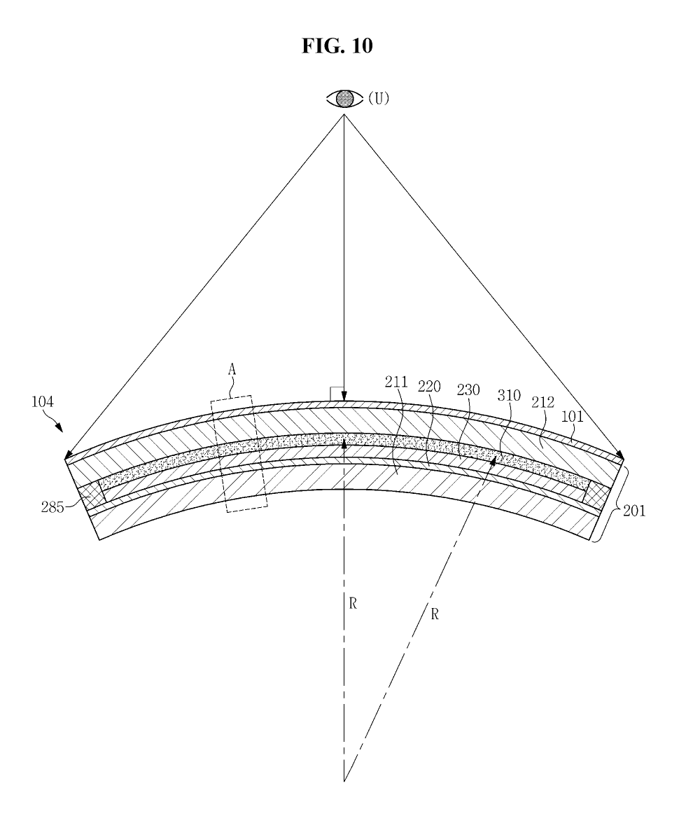

Hereinafter, a display device 104 according to a fourth exemplary embodiment will be described with reference to FIGS. 10 through 12.

FIG. 10 is a view illustrating a structure of the display device 104 according to the fourth exemplary embodiment. The display device 104 according to the fourth exemplary embodiment may be a curved-type display device. For Example, the display device 104 may have a curved structure having a radius of curvature R, and a convex surface may be seen by a user U.

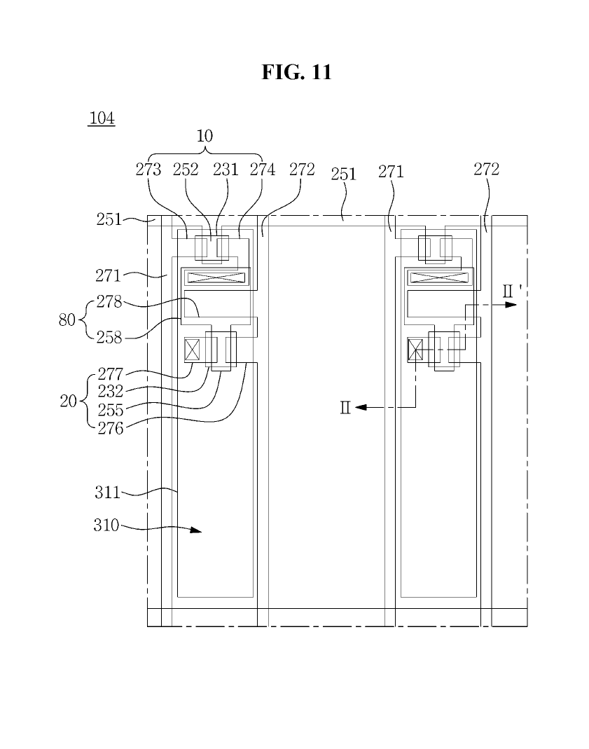

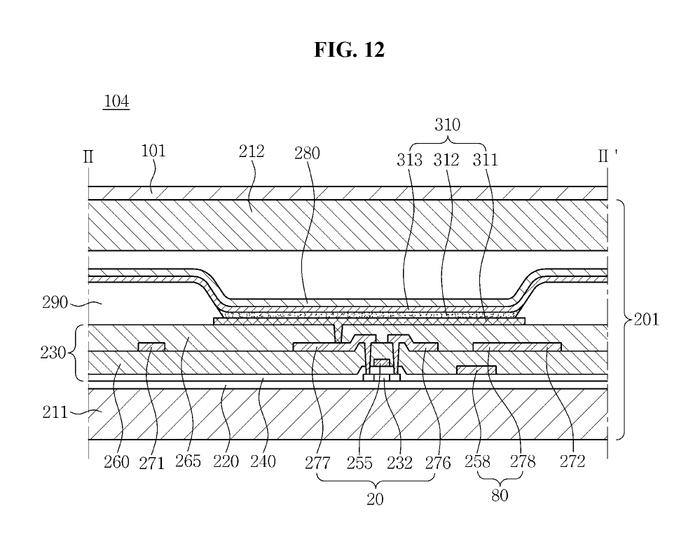

FIG. 11 is a plan view illustrating portion “A” of FIG. 10, and FIG. 12 is a cross-sectional view taken along line II -II′ of FIG. 11.

The display device 104 according to the fourth exemplary embodiment may include a display panel 201 and an optical film 101 disposed on the display panel 201. For Example, the display device according to the fourth exemplary embodiment may be an organic light emitting diode display device (OLED display device) 104.

The OLED display device 104 according to the fourth exemplary embodiment may include a substrate 211, a driving circuit 230, an organic light emitting diode (OLED) 310, an encapsulation substrate 212, and an optical film 101. The OLED display device 104 may further include a buffer layer 220 and a pixel defining layer 290.

The substrate 211 may include an insulating substrate, which is formed of, for example, glass, quartz, ceramic, plastic and the like. However, the fourth embodiment is not limited thereto, and the substrate 211 may also be made of a metal material, such as stainless steel and the like.

The buffer layer 220 may be disposed on the substrate 211. The buffer layer 220 may include one or more layers selected from a variety of inorganic layers and organic layers. However, the buffer layer 220 may not be always necessary, and may be omitted.

The driving circuit 230 may be disposed on the buffer layer 220. The driving circuit 230 may include a plurality of TFTs 10 and 20 and may drive the OLED 310. For example, the OLED 310 may display an image by emitting light according to a driving signal applied from the driving circuit 230.

FIGS. 11 and 12 illustrate an active matrix-type organic light emitting diode display device (AMOLED display device) 104 having a 2Tr-1Cap structure. For example, the 2Tr-1Cap structure may include the two TFTs 10 and 20 and a capacitor 80 in one pixel. However, the fourth embodiment is not limited thereto. In some embodiments, the OLED display device 104 may have many different structures including three or more TFTs and two or more capacitors in one pixel, and may further include additional wirings. Herein, the term “pixel” refers to the smallest unit for displaying an image. The OLED display device 104 may display an image using a plurality of pixels.

Each pixel may include the switching TFT 10, the driving TFT 20, the capacitor 80, and the OLED 310. Herein, a structure including the switching TFT 10, the driving TFT 20, and the capacitor 80 may be referred to as the driving circuit 230. The driving circuit 230 may include a gate line 251 arranged along a direction and a data line 271 and a common power line 272 insulated from and intersecting the gate line 251. The pixel may be defined by the gate line 251, the data line 271, and the common power line 272, but is not limited thereto. The pixel may also be defined by a black matrix or the pixel defining layer 290.

The OLED 310 may include a first electrode 311, an organic light emitting layer 312 disposed on the first electrode 311, and a second electrode 313 disposed on the organic light emitting layer 312. The organic light emitting layer 312 may be made of low molecular weight organic materials or high molecular weight organic materials. In the OLED 310, holes and electrons are injected from the first electrode 311 and the second electrode 313 into the organic light emitting layer 312, respectively. The hole and the electron are combined with each other to form an exciton, and the OLED may emit light by energy generated when the exciton falls from an excited state to a ground state.

The capacitor 80 may include a pair of capacitor plates 258 and 278 with an interlayer insulating layer 260 interposed therebetween. Herein, the interlayer insulating layer 260 may be a dielectric material. Capacitance of the capacitor 80 may be determined by electric charges stored in the capacitor 80 and voltage across the pair of capacitor plates 258 and 278.

The switching TFT 10 may include a switching semiconductor layer 231, a switching gate electrode 252, a switching source electrode 273, and a switching drain electrode 274. The driving TFT 20 may include a driving semiconductor layer 232, a driving gate electrode 255, a driving source electrode 276, and a driving drain electrode 277. In addition, the semiconductor layers 231 and 232 may be insulated from the gate electrodes 252 and 255 by the gate insulating layer 240.

The switching TFT 10 may function as a switching device which selects a pixel to perform light emission. The switching gate electrode 252 may be connected to the gate line 251. The switching source electrode 273 may be connected to the data line 271. The switching drain electrode 274 may be spaced apart from the switching source electrode 273 and may be connected to one of the capacitor plates 258.

The driving TFT 20 may apply a driving power to the first electrode 311, which serves as a pixel electrode, such that the organic light emitting layer 312 of the OLED 310 in a selected pixel may emit light. The driving gate electrode 255 may be connected to the capacitor plate 258 connected to the switching drain electrode 274 (FIG. 11). The driving source electrode 276 and the other one of the capacitor plates 278 may be respectively connected to the common power line 272. The driving drain electrode 277 may be connected to the first electrode 311, which serves as a pixel electrode of the OLED 310, through a contact hole formed on a planarization layer 265 (FIG. 12).

With the above-described structure, the switching TFT 10 may be operated by a gate voltage applied to the gate line 251, and may function to transmit a data voltage applied to the data line 271 to the driving TFT 20. A voltage equivalent to a difference between a common voltage applied from the common power line 272 to the driving TFT 20 and the data voltage transmitted from the switching TFT 10 may be stored in the capacitor 80, and current corresponding to the voltage stored in the capacitor 80 may flow to the OLED 310 through the driving TFT 20, such that the OLED 310 may emit light.

According to the fourth exemplary embodiment, the first electrode 311 may be formed as a reflective layer and the second electrode 313 may be formed as a transflective layer. Accordingly, light generated from the organic light emitting layer 312 may be emitted through the second electrode 313. Therefore, the OLED display device 104 according to the fourth exemplary embodiment may be provided in a top-emission structure.

At least one of a hole injection layer (HIL) and a hole transporting layer (HTL) may be disposed between the first electrode 311 and the organic light emitting layer 312. Further, at least one of an electron transporting layer (ETL) and an electron injection layer (EIL) may be disposed between the organic light emitting layer 312 and the second electrode 313.

The pixel defining layer 290 may have an aperture. The aperture of the pixel defining layer 290 may expose a portion of the first electrode 311. The first electrode 311, the organic light emitting layer 312, and the second electrode 313 may be sequentially laminated in the aperture of the pixel defining layer 290. Herein, the second electrode 313 may be formed not only on the organic light emitting layer 312 but also on the pixel defining layer 290. Meanwhile, the HIL, HTL, ETL, and EIL may be disposed between the pixel defining layer 290 and the second electrode 313. The OLED 310 may generate light by the organic light emitting layer 312 disposed in the aperture of the pixel defining layer 290. Accordingly, the pixel defining layer 290 may define light emission areas.

A protection layer 280 may be disposed on the second electrode 313. The protective layer 280 is configured to protect the OLED 310 from the external environment. The protection layer 280 may be also referred to as a capping layer.

The encapsulation substrate 212 may be disposed on the protection layer 280. The encapsulation substrate 212 may serve to seal the OLED 310, along with the substrate 211. In order to seal the OLED 310, a sealing member 285 may be disposed at an edge portion between the substrate 211 and the encapsulation substrate 212.

The encapsulation substrate 212 may include an insulating substrate formed of, for example, glass, quartz, ceramic, plastic or the like, as in the substrate 211. A portion between the substrate 211 and the encapsulation substrate 212 is referred to as a display panel 201.

The optical film 101 may be disposed on the display panel 201. In other words, the optical film 101 may be disposed on the encapsulation substrate 212, which corresponds to a display unit of the display panel 201. The optical film 101 according to the first exemplary embodiment may be used as the optical film 101 according to the present exemplary embodiment. Since the optical film 101 is fully described in the related description of the first exemplary embodiment, the detailed description will be omitted to avoid repetition.

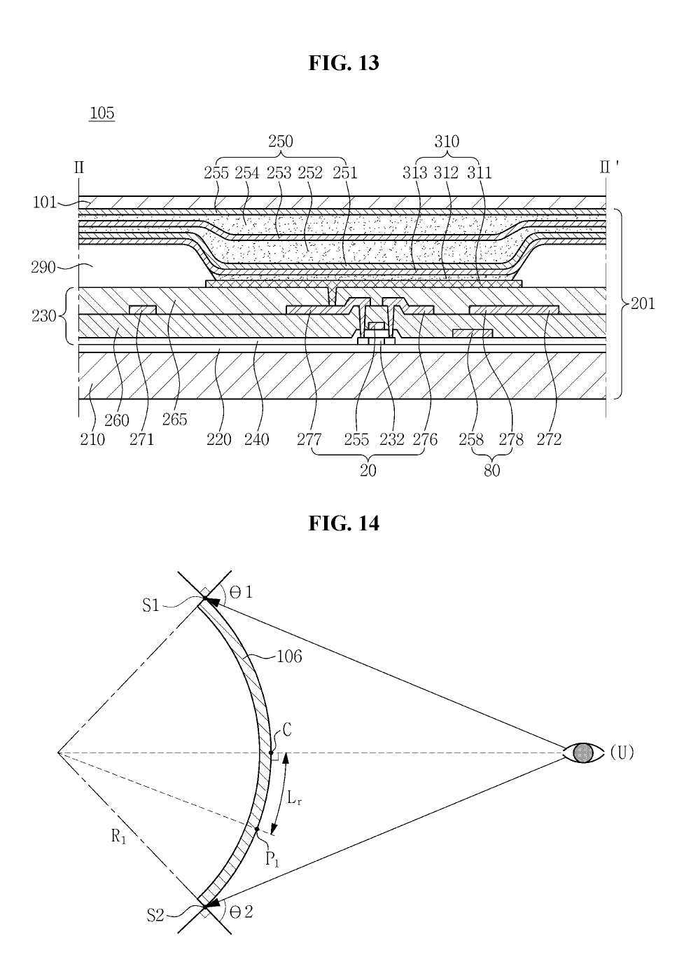

Hereinafter, a fifth exemplary embodiment will be described with reference to FIG. 13. FIG. 13 is a cross-sectional view illustrating an OLED display device 105 according to a fifth exemplary embodiment.

The OLED display device 105 according to the fifth exemplary embodiment may include a thin film encapsulation layer 250 disposed on an OLED 310.

The thin film encapsulation layer 250 may include one or more inorganic layers 251, 253, and 255, and one or more organic layers 252 and 254. The thin film encapsulation layer 250 may have a structure where the inorganic layers 251, 253, and 255 and the organic layers 252 and 254 are alternately laminated. In this regard, the inorganic layer 251 may be disposed closest to the OLED 310. Although the thin film encapsulation layer 250, illustrated in FIG. 13, includes three inorganic layers 251, 253, and 255, and two organic layers 252 and 254, the fifth exemplary embodiment is not limited thereto.

The inorganic layers 251, 253, and 255 may include one or more inorganic materials of Al₂O₃, TiO₂, ZrO, SiO₂, AlON, AlN, SiON, Si₃N₄, ZnO, and Ta₂O₅. The inorganic layers 251, 253, and 255 may be formed using methods such as chemical vapor deposition (CVD) or atomic layer deposition (ALD). However, the fifth exemplary embodiment is not limited thereto, and the inorganic layers 251, 253, and 255 may be formed using various methods known to those skilled in the art.

The organic layers 252 and 254 may include polymer-based materials. Herein, the polymer-based materials may include, for example, an acrylic resin, an epoxy resin, polyimide, and polyethylene. The organic layers 252 and 254 may be formed through a thermal deposition process. The thermal deposition process for forming the organic layers 252 and 254 may be performed in a range of temperatures that may not damage the OLED 310. However, the fifth exemplary embodiment is not limited thereto, and the organic layers 252 and 254 may be formed using various methods known to those skilled in the pertinent art.

The inorganic layers 251, 253, and 255 having a high density of thin films may prevent or efficiently reduce infiltration of moisture or oxygen.

Moisture and oxygen that passes through the inorganic layers 251, 253, and 255 may be further blocked by the organic layers 252 and 254. The organic layers 252 and 254 may show a relatively low moisture-infiltration preventing efficiency compared to the inorganic layers 251, 253, and 255. However, the organic layers 252 and 254 may also serve as a buffer layer to reduce stress between the respective inorganic layers 251, 253, and 255 and the organic layers 252 and 254, in addition to the ability of preventing moisture infiltration. Further, since the organic layers 252 and 254 have planarizing properties, the uppermost surface of the thin film encapsulation layer 250 may be planarized.

The thin film encapsulation layer 250 may have a thickness of about 10 μm or less. Accordingly, the OLED display device 105 may be formed to have an overall thickness significantly small.

In a case where the thin film encapsulation layer 250 is disposed on the OLED 310, the encapsulation substrate 212 of FIG. 12 may be omitted. When the encapsulation substrate 212 is omitted, flexibility of the OLED display device 105 may be enhanced.

The optical film 101 may be disposed on the thin film encapsulation layer 250. The optical film 101 according to the first exemplary embodiment may be used as the optical film 101 according to the present exemplary embodiment.

Hereinafter, color shift effect of the display device 105 when the optical film 101 according to the first exemplary embodiment is applied to the display panel 106 will be described.

Herein, the display panel 106 may have a curve, and a convex surface thereof may be disposed toward a user U, which is similar to the OLED display device 104 according to the fourth exemplary embodiment. Examples of the curved-type display panel 106 may include a display panel for a wearable display device, such as a smart watch.

Referring to FIG. 14, when the user U looks at the display panel 106 from the front side, a viewing angle θ0 in a direction toward a center portion C of the display panel 106 may be about 0 degree. On the other hand, when the user U looks at edge portions S1 and S2 of the display panel 106, the viewing angle, that is, a viewing angle θ1, may increase.

Color shift may occur when the viewing angle of the user U increases. The color shift may also be referred to as white angular dependency (WAD). The WAD refers to a phenomenon in which when a white light is emitted from a display device, the white light may be observed from the front side of the display device, while a light of a different color, for example, a blue color, may be observed from the lateral side thereof, because of a wavelength shift caused by a light path difference. Hereinafter, the white angular dependency (WAD) and the color shift (hereinafter, also referred to as “WAD”) are to be understood to have the same meaning.

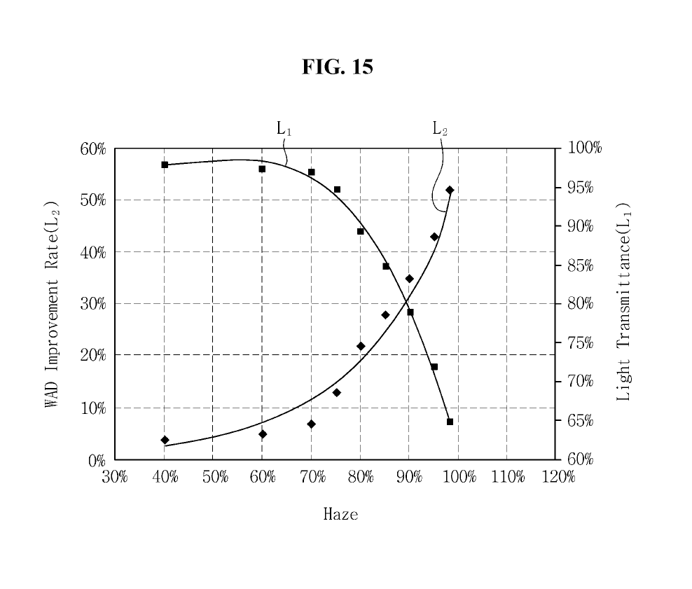

FIG. 15 is a graph illustrating a WAD improvement rate L2 and a light transmittance L1 based on a haze value of an optical film.

Referring to FIG. 15, it can be inferred that the WAD improvement rate L2 and the light transmittance L1 based on the haze value of the optical film may have a complementary relationship therebetween.

An optical film commonly used in display devices so as to prevent WAD may have a uniform haze value over the entire optical film. Accordingly, when an optical film having a great haze value is used so as to prevent WAD in the lateral side thereof, although the WAD in the lateral side may be prevented, the light efficiency of the display device may be diminished due to a decrease in light transmittance. In particular, the optical film having a great haze value is disposed even in the front side where WAD hardly occurs, and thus the light transmittance of the front side is also decreased.

The optical film 101 according to the first exemplary embodiment may have a haze value gradually increasing from a center portion of the optical film 101 toward an edge portion thereof. When such an optical film 101 is used in a display device, the WAD occurring in the edge portion thereof may be efficiently prevented. In addition, the center portion of the optical film 101 disposed in a center portion of the display device may have a relatively lower haze value and relatively high light transmittance, such that light transmittance loss in the front side of the display device may be minimized.

A simulation test is carried out in order to identify an effect of WAD prevention and the effect on preventing the light-transmittance loss. In the simulation test, the display panel 106 which has a length (width) of about 70 millimeters (mm) and has a radius of curvature of about 33.42 mm is used and CIE 1931 chromatic coordinates is applied.

A distance (Lr) from a center portion C of the display panel 106 to a spatial point P1 thereof, a viewing angle, and a WAD (panel Δu′v′) of the spatial point P1 are calculated, and a target WAD (target Δu′v′) of the spatial point P1 is determined. The target WAD (target Δu′v′) is a target value of the WAD improvement, and may refer to a WAD improved by the optical film 101.

A WAD improvement rate required for achieving the target WAD (target Δu′v′) is calculated, and a required haze value corresponding to the WAD improvement rate is calculated referring to a graph illustrated in FIG. 15. In this regard, a maximum allowable WAD (max Δu′v′) is set to be about 0.048 (max Δu′v′=0.048) or less. When a WAD is about 0.048 or less, a user may hardly notice the WAD.

The results of the simulation test are described in Table. 1.

TABLE 1

| Distance | Viewing | | | WAD | | |
|---|---|---|---|---|---|---|
| (Lr) | angle | Panel | Target | improvement | Required | |
| (mm) | (°) | Δu‘v’ | Δu‘v’ | rate | Haze value | Others |
| 0.00 | 0 | 0 | 0 | 0% | 0% | Center portion |
| 5.83 | 10 | 0.004 | 0.004 | 0% | 0% | |
| 11.67 | 20 | 0.0178 | 0.016 | 10% | 68% | |
| 17.50 | 30 | 0.040 | 0.034 | 15% | 75% | |
| 23.33 | 40 | 0.0655 | 0.048 | 27% | 86% | |
| 29.17 | 50 | 0.085 | 0.048 | 44% | 95% | |
| 35.00 | 60 | 0.099 | 0.048 | 52% | 98% | Edge portion |

In this regard, the WAD improvement rate is determined by the following Formula 2.

WAD improvement rate (%)=[1−(Target Δu′v′/Panel Δu′v′)]×100 [FORMULA 2]

Referring to Table. 1, in a case where the optical film 101 is not disposed in the display panel 106, for example, a WAD (Δu′v′) of an edge portion of the display panel 106, which has a distance (Lr) of about 35 mm from the center portion C thereof, may be about 0.099. In order to achieve a WAD of 0.048 (Target Δu′v′=0.048) in the edge portion, a WAD improvement rate of about 52% is needed, and to this end, a haze value of 98% is needed.

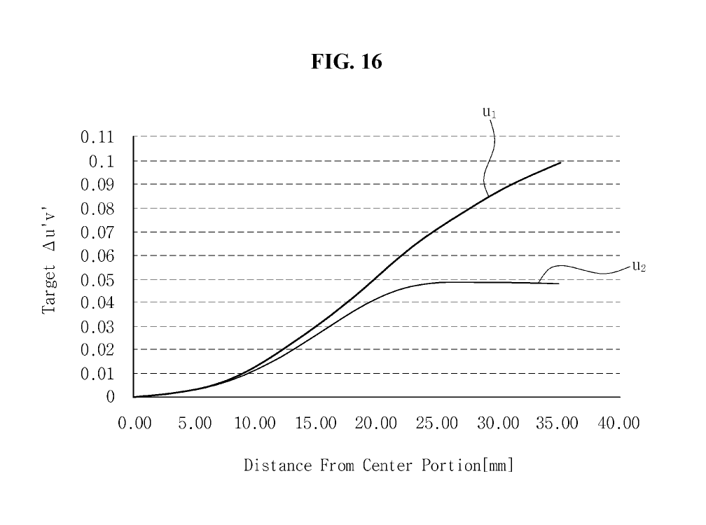

FIG. 16 is a graph illustrating WAD improvement, that is, in particular, a graph illustrating WAD improvement of a display panel when an optical film having a “required haze value” determined by Table 1 is used.

Referring to FIG. 16, U1 denotes a WAD based on the distance (Lr) from the center portion C of the display panel 106, in a case where an optical film is not applied to the display panel 106. On the other hand, U2 denotes WAD in a case where an optical film having a required haze value determined based on a corresponding distance illustrated in Table 1 is used.

Meanwhile, in a case where an optical film of which an entire surface has a haze value of about 98% is used in order to improve WAD in the edge portion of the display panel 106, a light transmittance of the center portion C of the display panel 106 may decrease to about 65%. In other words, the light transmittance loss of the center portion C may be about 35%. When using another optical film in which the center portion C has a haze value of about 0% and the edge portion has a haze value of about 98%, a light transmittance of the center portion C of the display panel may be 100%, which is essentially 154% compared to the light transmittance of the center portion C (65%) of the display panel using the optical film of which an entire surface has a haze value of about 98% as is evident based on the equation shown here: (100%/65%)×100=154%.

Table 2 illustrates a relationship between a haze value and a light transmittance, and also illustrates ratios of light transmittances of a center portion of a display panel using an optical film having a haze value of about 0% in a center portion ( 100% of transmittance), compared to those in which optical films wherein the entire surface has same haze values of from about 40% to about 98%, respectively, is used.

TABLE 2

| | Ratio of light transmittance in |
|---|---|
| Relationship between haze | center portion having 0% of |
| value and light transmittance | haze value compared to those |

| Haze | Transmittance | having haze value of the left |
|---|---|---|
| 40% | 98% | 102% |
| 60% | 98% | 103% |
| 70% | 97% | 103% |
| 75% | 95% | 105% |
| 80% | 90% | 112% |
| 85% | 85% | 118% |
| 90% | 79% | 127% |
| 95% | 72% | 139% |
| 98% | 65% | 154% |

Therefore, when the optical films according to the exemplary embodiments of the present disclosure are used, WAD occurring in the edge portion of a display device may be prevented, and also a decrease in light transmittance in the center portion of the display device may be prevented.

From the foregoing, it will be appreciated that various embodiments in accordance with the present disclosure have been described herein for purposes of illustration, and that various modifications may be made without departing from the scope and spirit of the present teachings. Accordingly, the various embodiments disclosed herein are not intended to be limiting of the true scope and spirit of the present teachings.

What is claimed is:

1. An optical film comprising:
a low haze portion having a haze value of about 60% or less; and
a high haze portion having a haze value of about 80% or more,
wherein the high haze portion is disposed in an outer side of the low haze portion.

2. The optical film of claim 1, wherein the low haze portion has a haze value in a range of about 30% to about 60%.

3. The optical film of claim 1, wherein the low haze portion has a haze gradient in which a haze value increases along a direction from a center portion to an edge portion.

4. The optical film of claim 1, wherein the high haze portion has a haze value in a range of about 80% to about 98%.

5. The optical film of claim 1, wherein the high haze portion has a haze gradient in which a haze value increases along a direction from a center portion to an edge portion.

6. The optical film of claim 1, further comprising at least one intermediate portion between the low haze portion and the high haze portion.

7. The optical film of claim 6, wherein the intermediate portion has a haze value in a range of about 60% to about 80%.

8. The optical film of claim 1, wherein the low haze portion and the high haze portion comprise a light transmission member and light scattering particles dispersed in the light transmission member.

9. The optical film of claim 8, wherein the light scattering particle comprises at least one of an acrylic resin, a polystyrene (PS) resin, a polyvinyl chloride resin, a polycarbonate (PC) resin, a polyethylene terephthalate (PET) resin, a polyethylene (PE) resin, a polypropylene (PP) resin, a polyimide (PI) resin, glass and silica.

10. The optical film of claim 8, wherein the light transmission member comprises at least one of a polyester resin, an acrylic resin, a cellulose resin, a polyolefin resin, a polyvinyl chloride resin, a polycarbonate resin, a phenolic resin and a urethane resin.

11. A display device comprising:
a display panel; and
an optical film on the display panel,
wherein the optical film comprises a low haze portion having a haze value of about 60% or less and a high haze portion having a haze value of about 80% or more, and
the high haze portion is disposed in an outer side of the low haze portion.

12. The display device of claim 11, wherein the low haze portion has a haze value in a range of about 30% to about 60%.

13. The display device of claim 11, wherein the low haze portion has a haze gradient in which a haze value increases along a direction from a center portion to an edge portion.

14. The display device of claim 11, wherein the high haze portion has a haze value in a range of about 80% to about 98%.

15. The display device of claim 11, wherein the high haze portion has a haze gradient in which a haze value increases along a direction from a center portion to an edge portion.

16. The display device of claim 11, further comprising at least one intermediate portion between the low haze portion and the high haze portion.

17. The display device of claim 16, wherein the intermediate portion has a haze value in a range of about 60% to about 80%.

18. The display device of claim 11, wherein the low haze portion and the high haze portion comprise a light transmission member and light scattering particles dispersed within the light transmission member.

19. The display device of claim 18, wherein the light scattering particle comprises at least one of an acrylic resin, a polystyrene (PS) resin, a polyvinyl chloride resin, a polycarbonate (PC) resin, a polyethylene terephthalate (PET) resin, a polyethylene (PE) resin, a polypropylene (PP) resin, a polyimide (PI) resin, glass and silica.

20. The display device of claim 18, wherein the light transmission member comprises at least one of a polyester resin, an acrylic resin, a cellulose resin, a polyolefin resin, a polyvinyl chloride resin, a polycarbonate resin, a phenolic resin and a urethane resin.

21. A display device of claim 11, wherein the display panel comprises:
a substrate;
a first electrode on the substrate;
an organic light emitting layer on the first electrode; and
a second electrode on the organic light emitting layer.

22. The display device of claim 21, wherein the display panel further comprises a thin film encapsulation layer on the second electrode.
